(19) United States
(12) Patent Application Publication
(10) Pub. No.: US 2014/0164683 A1
(43) Pub. Date: Jun. 12, 2014

(54) NONVOLATILE MEMORY APPARATUS, OPERATING METHOD THEREOF, AND DATA PROCESSING SYSTEM HAVING THE SAME

(71) Applicant: SK HYNIX INC., Icheon-si Gyeonggi-do (KR)

(72) Inventor: Min Chul SHIN, Icheon-si Gyeonggi-do (KR)

(73) Assignee: SK HYNIX INC., Icheon-si Gyeonggi-do (KR)

(21) Appl. No.: 13/846,779

(22) Filed: Mar. 18, 2013

(30) Foreign Application Priority Data
Dec. 12, 2012 (KR) 10-2012-0144309

(51) Int. Cl. G11C 7/10; G06F 12/02

(52) U.S. Cl. CPC G11C 7/10; G06F 12/0246
USPC 711/103; 365/189.14

(57) ABSTRACT

A nonvolatile memory apparatus includes: a memory cell array; a write driver/sense amplifier (WD/SA) configured to program data into the memory cell array or read data from the memory cell array; and an I/O controller configured to receive the read data from the memory cell array from the WD/SA, decide a coding mode based on comparison data between write data and the read data, encode the write data according to the coding mode, and provide the encoded data to the WD/SA.

### CROSS-REFERENCES TO RELATED APPLICATION

The present application claims priority under 35 U.S.C. §119(a) to Korean application number 10-2012-0144309, filed on Dec. 12, 2012, in the Korean Intellectual Property Office, which is incorporated herein by reference in its entirety.

### BACKGROUND

1. Technical Field

The present invention generally relates to a semiconductor apparatus, and more particularly, to a nonvolatile memory apparatus, an operating method thereof, and a data processing system having is the same.

2. Related Art

A nonvolatile memory apparatus represented by a flash memory, a phase change RAM (PCRAM), a resistive RAM (ReRAM), a magnetic RAM (MRAM) and the like has developed from a single level cell (SLC) method for writing single-level data to a multi-level cell (MLC) method for writing multi-level data.

The nonvolatile memory apparatus based on the SLC method may determine whether or not to write data, according to a comparison result between data to be written and data written in a cell, in order to reduce an operation current during a program operation. That is, when the data to be written are identical to the data written in the cell, the nonvolatile memory device may not perform the program operation, or when most of the data to be written have different levels from the data written in the memory cell, the nonvolatile memory device may invert and write the data (data inversion method), thereby reducing a write current.

The data inversion method has a significant current reduction effect in an SLC, but has no current reduction effect in an MLC. Therefore, a data input/output control method suitable for the MLC method is required.

### SUMMARY

In one embodiment of the present invention, a nonvolatile memory apparatus includes: a memory cell array; a write driver/sense amplifier (WD/SA) configured to program data into the memory cell array or read data from the memory cell array; and an I/O controller configured to receive the read data from the memory cell array from the WD/SA, decide a coding mode based on comparison data between write data and the read data, encode the write data according to the coding mode, and provide the encoded data to the WD/SA.

In an embodiment of the present invention, an operating method of a nonvolatile memory apparatus includes the steps of: reading data from a memory cell array in which program is to be performed, as a write command is inputted from a host; deciding a coding mode based on comparison data obtained by comparing write data and the read data from the memory cell array; encoding the write data according to the coding mode; and programming the encoded data into a memory cell.

In an embodiment of the present invention, a data processing system includes: a nonvolatile memory apparatus; and a memory controller configured to access the nonvolatile memory apparatus in response to a request of a host, wherein the nonvolatile memory apparatus includes: a memory cell array; a WD/SA configured to program data into the memory cell array or read data from the memory cell array; and an I/O controller configured to receive the read data from the memory cell array from the WD/SA, decide a coding mode based on comparison data between write data and the read data, encode the write data according to the coding mode, and provide the encoded data to the WD/SA.

In an embodiment of the present invention, a data processing system includes: a processor configured to control overall operations; a working memory configured to store applications, data, and control signals which are required for operating the processor; a nonvolatile memory apparatus accessed by the processor; and a user interface configured to perform data I/O between the processor and a user, wherein the nonvolatile memory apparatus includes: a memory cell array; a WD/SA configured to program data into the memory cell array or read data from the memory cell array; and an I/O controller configured to receive the read data from the memory cell array from the WD/SA, decide a coding mode based on comparison data between write data and the read data, encode the write data according to the coding mode, and provide the encoded data to the WD/SA.

### BRIEF DESCRIPTION OF THE DRAWINGS

Features, aspects, and embodiments are described in conjunction with the attached drawings, in which:

FIG. 1 is a configuration diagram of a nonvolatile memory apparatus according to one embodiment of the present invention;

FIG. 2 illustrates an I/O controller of FIG. 1;

FIG. 3 is a table for explaining the types of a coding mode based on data comparison results;

FIG. 4 is a table for explaining an example of a data write method based on a coding mode;

FIGS. 5 and 6 are flowcharts for explaining the operation of the nonvolatile memory apparatus according to the embodiment of the present invention;

FIG. 7 is a configuration diagram of a data processing system according to the embodiment of the present invention; and

FIG. 8 is a configuration diagram of a data processing system according to another embodiment of the present invention.

### DETAILED DESCRIPTION

Hereinafter, a nonvolatile memory apparatus, an operating method thereof, and a data processing system having the same according to the present invention will be described below with reference to the accompanying drawings through exemplary embodiments.

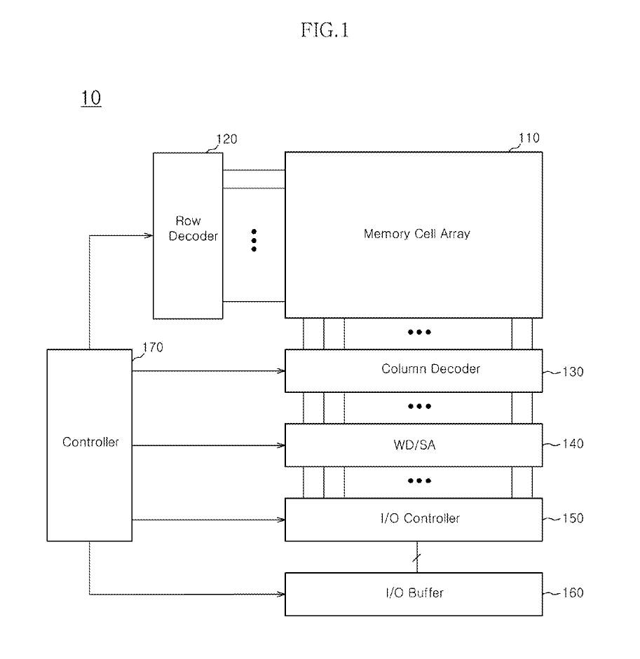

Referring to FIG. 1, the nonvolatile memory apparatus 10 may include a memory cell array 110, a row decoder 120, a column decoder 130, a write driver/sense amplifier (WD/SA) 140, an I/O controller 150, an I/O buffer 160, and a controller 170. For example, the WD/SA 140 may be configured as one block, but may include a write driver block and a sense amplifier block which are configured separately from each other.

The memory cell array 110 may include a plurality of unit memory cells, for example, a plurality of nonvolatile memory cells connected between a plurality of word lines and a plurality of bit lines, respectively. Furthermore, the memory cell array 110 may include at least one of blocks, and each of the unit memory cells may include an MLC.

The row decoder 120 and the column decoder 130 may be configured to select one word line among the plurality of word lines and one bit line among the plurality of bit lines according to an address signal provided from the controller 170.

The WD/SA 140 may be configured to receive data provided from the controller 170 through the I/O buffer 160 and the I/O controller 150 and write (or program) the received data into the memory cell array 110 during a program operation. Furthermore, the WD/SA 140 may be configured to read data from the memory cell array 110 and provide the read data to the controller 170 through the I/O controller 150 and the I/O buffer 160 during a read operation.

The I/O controller 150 may be configured to receive data to be written (hereafter, referred to as ‘write data’) through the I/O buffer 160, compare data of memory cells read by the WD/SA 140 according to an address provided from the controller 170, decide a coding mode according to the comparison result, encode the write data according to the coding mode, and provide the encoded data to the WD/SA 140, during a program operation. Furthermore, the I/O controller 150 may be configured to decode data read by the WD/SA 140 according to the decided coding mode and provide the decoded data to the I/O buffer 160, during a read operation.

A predetermined data length may be set to one program unit, and the coding mode may be decided for each program unit. The coding mode may be written as a tail bit at a designated position of a memory cell to be written (or programed). Therefore, during the read operation, the data and the tail bit of the memory cell may be read together, and the read data may be decoded according to the coding mode indicated by the tail bit.

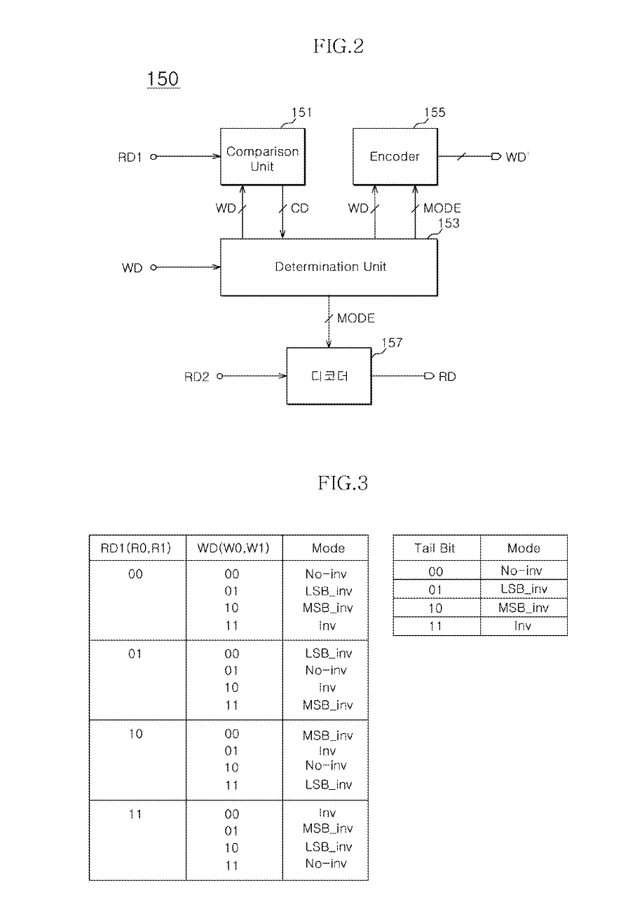

The I/O controller 150 may generate comparison data to indicate which bits were inverted, according to a comparison result between write data and read data. Furthermore, a comparison data occupying the largest portion of the comparison data is selected as a coding mode. When the selected coding mode and comparison data are identical to each other, the WD/SA 140 may be controlled to not write data into a memory cell in which the corresponding data is to be written. Accordingly, the write current and time may be reduced. The detailed descriptions thereof will be described below with reference to FIGS. 2 to 4.

The controller 170 may be configured to receive the address and data from a host (not shown), and control the peripheral circuits 120 to 160 of the memory cell array 110 to write data into the memory cell array 110, during the program operation. Furthermore, the controller 170 is configured to receive an address from the host and control the peripheral circuits 120 to 160 to transmit data read from the memory cell array 110 to the host, during the read operation.

For reference, the program operation may correspond to a write mode or writing operation.

Referring to FIG. 2, the I/O controller 150 according to the embodiment of the present invention may include a comparison unit 151, a determination unit 153, an encoder 155, and a decoder 157.

The comparison unit 151 may be configured to receive write data WD through the I/O buffer 160 and the determination unit 153, receive data RD1 read from a memory cell into which the data is to be written from the WD/SA 140, generate comparison data CD by comparing the write data WD and the read data RD1, and provide the comparison data CD to the determination unit 153. The comparison unit 151 may include an XOR operating unit to compare the write data WD and the read, but the present invention is not limited thereto. Furthermore, the comparison data CD may include data indicating which bits were inverted.

The determination unit 153 may be configured to select comparison data occupying the largest portion of the comparison data CD as the coding mode MODE.

The encoder 155 may be configured to receive the write data WD and the coding mode MODE from the determination unit 153, encode the write data WD according to the coding mode MODE, and provide the encoded data WD′ with the tail mode to the WD/SA 140.

The decoder 157 may be configured to receive data RD2 read from a memory cell from the WD/SA 140, receive the coding mode MODE provided from the determination unit 153, and output decoded data RD to the I/O buffer 160.

Referring to FIG. 3, according to the levels of the write data WD and the data RD1 read from the memory cell into which the data is to be written, the coding mode MODE may be divided into a non-inversion mode No-inv, an LSB inversion mode LSB-inv, an MSB inversion mode MSB-Inv, and an inversion mode Inv.

Furthermore, a tail bit of the non-inversion mode No-inv may be defined as 00, a tail bit of the LSB inversion mode LSB-inv may be defined as 01, a tail bit of the MSB inversion mode MSB-inv may be defined as 10, and a tail bit of the inversion mode Inv may be defined as 11.

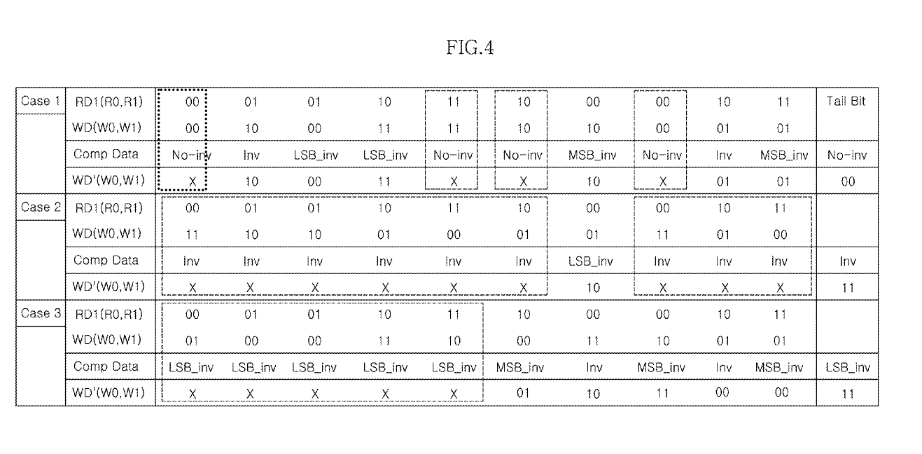

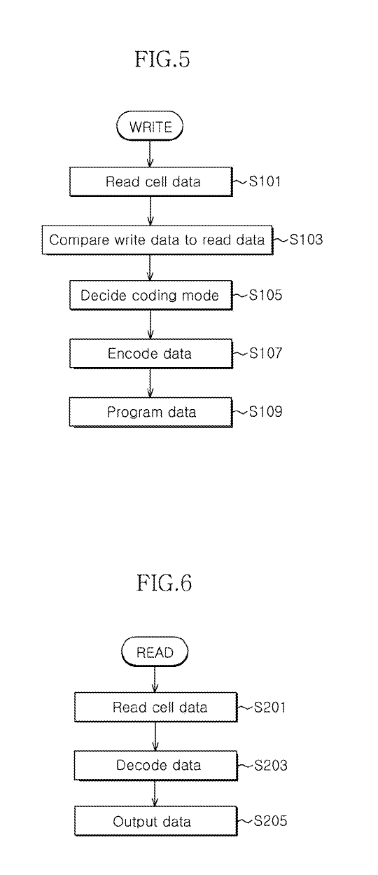

In FIG. 4, suppose that a data length n of 10 is one program unit.

Referring to FIG. 4, in Case 1, comparison data corresponding to the non-inversion mode No-inv among various comparison data CD obtained by comparing the read data RW1 by the write data WD occupy the largest portion (refer to a dotted-line box). For example, a data length n of FIG. 4 supposes 10 as one program unit. In this case 1, the coding mode may be decided as the non-inversion mode No-inv. Furthermore, the encoder 155 may control the WD/SA 140 to prohibit a write (program) operation of memory cells in which the decided coding mode No-inv is identical to the comparison data CD. Further, the encoder 155 may control the WD/SA 140 to write data into the other memory cells in which the decided coding mode No-inv is not identical to the comparison data CD, according to the non-inversion mode No-inv. That is, second, third, fourth, seventh, ninth, and tenth data at which the coding mode is not identical to the comparison data CD may be encoded according to the non-inversion mode No-inv and written into the memory cells. At this time, the tail bit 00 is stored together. Namely, the encoder 155 may provide the write data WD to the WD/SA 140, as the encoded data WD′.

In Case 2, comparison data corresponding to the inversion mode Inv occupies the largest portion (refer to a dotted-line box) among the various comparison data CD, such as, the non-inversion mode No-inv, the LSB inversion mode LSB-inv, the MSB inversion mode MSB-Inv, and the inversion mode Inv. In case 2, the coding mode may be decided as the inversion mode Inv. Furthermore, the seventh write data WD of 01 may be encoded into 10 according to the inversion mode Inv, and the encoded data WD′ of 10 and a tail bit of 11 written into a memory cell.

In Case 3, the coding mode may be decided when the LSB inversion mode LSB-inv (refer to a dotted-line box) is majority. In this case, encoded data WD′ obtained by inverting the LSBs of sixth to 11th write data WD and a tail bit of 11 are written into memory cells.

During the read operation, data of a memory cell and a tail bit may be read together, and the data of the memory cell may be decoded and outputted according to the tail bit. If a majority encoding mode is the non-inversion mode No-inv, the data read from the memory cell is provided to the I/O buffer 160 as it is. If the majority encoding mode is the inversion mode Inv, the read data is decoded by inverting all bits of the read data. If the majority mode is the LSB inversion mode LSB-inv, the LSB of read data is inverted too.

In case 1, the write operation of four cells (refer to a dotted-line box) having the non-inversion mode No-inv may be omitted. In case 2, the write operation of nine cells (refer to a dotted-line box) having the inverting mode may be omitted. In case 3, the write operation of five cells, corresponding to a half of the overall memory cells may be omitted. Therefore, the write current and time may be significantly reduced.

First, referring to FIG. 5, the program method will be described.

As a write command is inputted from a host, the controller 170 may operate the memory cell array 110 and the peripheral circuits 120 to 160 to perform a program operation, according to an address received from the host.

First, the WS/DA 140 may read data from memory cells at positions where a program operation may be to be performed and provides the read data RD1 to the I/O controller 150, at step S101. Furthermore, the I/O controller 150 may compare write data WD received from the I/O buffer 160 to the read data RD1 at step S103, and decide a coding mode MODE according to the comparison result at step S105.

At this time, the write data WD and the read data RD1 may be compared by an XOR operation, and the comparison data CD may include information indicating whether the respective bits thereof were inverted or not. Furthermore, the coding mode MODE may be selected as comparison data occupying the largest portion of the comparison data CD. That is, the coding mode may be decided as a majority comparing data among the various comparing data.

When the coding mode MODE may be decided, the I/O controller 150 may encode the write data WD according to the decided coding mode MODE at step S107, and provide the encoded data WD′ and a tail bit indicating the coding mode MODE to the WD/SA 140 such that the encoded data WD′ is written into a memory cell. At this time, the program operation for a memory cell having the same comparison data CD as the coding mode MODE is prohibited, and a program operation is performed only for a memory cell having different comparison data CD from the coding mode MODE. Accordingly, the current and time required for the program operation may be reduced.

When a read command and address may be provided from a host, the controller 170 may operate the memory cell array 110 and the peripheral circuits 120 to 160 to perform a read operation, according to an address received from the host.

First, data RD2 and a tail bit may be read from corresponding memory cells by the WD/SA 140 at step S201. The read data RD2 are provided to the I/O controller 150, and the I/O controller 150 decodes the read data RD2 according to the tail bit, that is, the coding mode at step S203.

Furthermore, the decoded data RD is provided to the controller 170 through the I/O buffer 160.

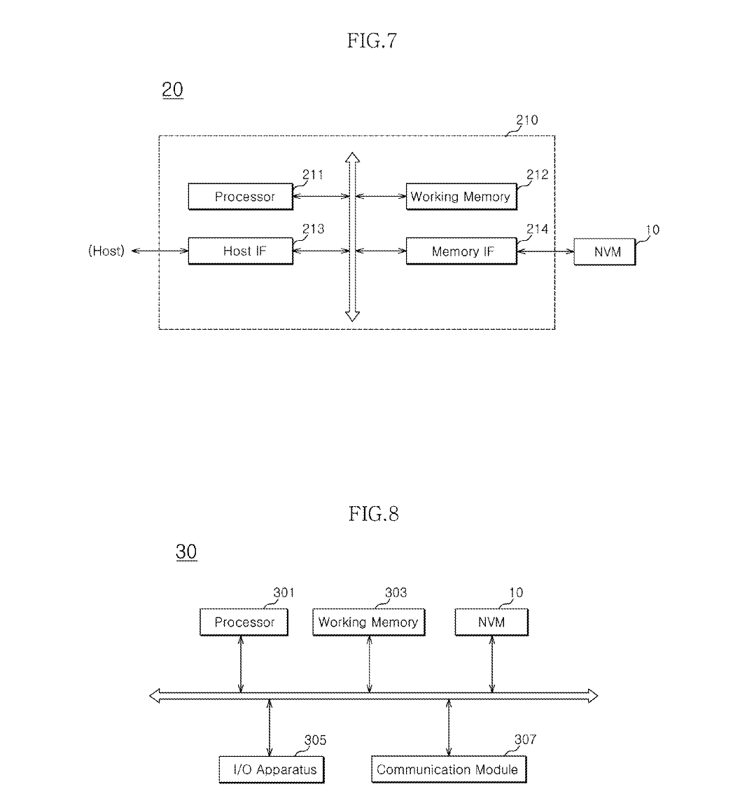

Referring to FIG. 7, the data processing system 20 may include a memory controller 210 connected between a host and a nonvolatile memory apparatus 10.

The memory controller 210 may be configured to access the nonvolatile memory apparatus 10 in response to a request of the host, and may include a processor 211, a working memory 212, a host interface 213, and a memory interface 214.

The processor 211 may control overall operations of the memory controller 210, and the working memory 212 may store applications, data, control signals and the like, which are required for operating the memory controller 210.

The host interface 213 may serve to convert a protocol for exchanging data/control signals between the host and the memory controller 210, and the memory interface 214 may serve to convert a protocol for exchanging data/control signals between the memory controller 210 and the nonvolatile memory apparatus 10.

The nonvolatile memory apparatus 10 may include the apparatus illustrated in FIG. 1, for example. Therefore, the nonvolatile memory apparatus 10 may encode write data in a coding mode which is decided according to comparison data between the write data and read data during a program operation, and then write the encoded data. When the coding mode is identical to the comparison data, program may be prohibited to thereby reduce the program current and time.

In the embodiment of the present invention, the data processing system illustrated in FIG. 7 may include a memory card, but the present invention is not limited thereto.

Referring to FIG. 8, the data processing system 30 illustrated in FIG. 8 may include a nonvolatile memory apparatus 10, a processor 301, a working memory 303, and an I/O apparatus 305. If necessary, the data processing system 30 may further include a communication module 307.

The processor 301 may include a central processing unit (CPU), and the working memory 303 may store application programs, data, control signals and the like, which are required for operating the data processing system 30. The I/O apparatus 305 may provide an environment in which a user can access the data processing system 30, and provide a data processing result of the data processing system 30 to the user.

The nonvolatile memory apparatus 10 may include the apparatus illustrated in FIG. 1, for example. Therefore, the nonvolatile memory apparatus 10 may encode write data in a coding mode which is decided according to comparison data between the write data and read data during a program operation, and then write the encoded data. When the coding mode is identical to the comparison data, program may be prohibited to thereby reduce the program current and time.

The data processing systems illustrated in FIGS. 7 and 8 may be utilized as a disc device, used as an internal/external memory card of a mobile electronic device, or used as an image processor and other application chips.

While certain embodiments have been described above, it will be understood to those skilled in the art that the embodiments described are by way of example only. Accordingly, the nonvolatile memory apparatus described herein should not be limited based on the described embodiments. Rather, the nonvolatile memory apparatus described herein should only be limited in light of the claims that follow when taken in conjunction with the above description and accompanying drawings.

What is claimed is:

1. A nonvolatile memory apparatus comprising:
a memory cell array;
a write driver/sense amplifier (WD/SA) configured to program data into the memory cell array and read data provided from the memory cell array; and
an I/O controller configured to receive the read data provided from the memory cell array from the WD/SA, decide a coding mode based on comparison data obtained by comparing write data and the read data, encode the write data according to the coding mode, and provide the encoded data to the WD/SA.

2. The nonvolatile memory apparatus according to claim 1, wherein the I/O controller comprises:
a comparison unit configured to compare the write data and the read data and generate comparison data;
a determination unit configured to receive the comparison data and select comparison data occupying the largest portion of the comparison data as the coding mode; and
an encoder configured to encode the write data according to the coding mode and provide the encoded data to the WD/SA.

3. The nonvolatile memory apparatus according to claim 2, wherein the encoder is configured to add a tail mode as coding mode into the encoded data and provide the encoded data to the WD/SA.

4. The nonvolatile memory apparatus according to claim 2, wherein the encoder is configured to control the WD/SA to prohibit a program operation of a memory cell, into which the corresponding write data is to be programmed when the coding mode is identical to the comparison data.

5. The nonvolatile memory apparatus according to claim 2, wherein the comparison data comprises inverted bit information of the write data and the read data.

6. The nonvolatile memory apparatus according to claim 2, wherein the comparison unit generates the comparison data based on an exclusive OR operation of the write data and the read data.

7. The nonvolatile memory apparatus according to claim 2, further comprising a decoder configured to decode the data read provided from the memory cell array according to the coding mode.

8. A data processing system comprising:
a nonvolatile memory apparatus; and
a memory controller configured to access the nonvolatile memory apparatus in response to a request of a host,
wherein the nonvolatile memory apparatus comprises:
a memory cell array;
a WD/SA configured to program data into the memory cell array or read data from the memory cell array; and
an I/O controller configured to receive the read data provided from the memory cell array from the WD/SA, decide a coding mode based on comparison data obtained by comparing write data and the read data, encode the write data according to the coding mode, and provide the encoded data to the WD/SA.

9. The data processing system according to claim 8, wherein the I/O controller comprises:
a comparison unit configured to compare the write data and the read data and generate comparison data;
a determination unit configured to receive the comparison data and select comparison data occupying the largest portion of the comparison data as the coding mode; and
an encoder configured to encode the write data according to the coding mode and provide the encoded data to the WD/SA.

10. The data processing system according to claim 9, wherein wherein the encoder is configured to generate the encoded data to include a tail bit and provide the encoded data to the WD/SA.

11. The data processing system according to claim 9, wherein the encoder controls the WD/SA to prohibit a program operation of a memory cell, into which the corresponding write data is to be programmed, when the coding mode is identical to the comparison data.

12. The data processing system according to claim 9, wherein the comparison data comprises inverted bit information of the write data and the read data.

13. The data processing system according to claim 9, further comprising a decoder configured to decode the data read from the memory cell array according to the coding mode.

14. A data processing system comprising:
a processor configured to control overall operations;
is a working memory configured to store applications, data, and control signals which are required for operating the processor;
a nonvolatile memory apparatus accessed by the processor; and
a user interface configured to perform data I/O between the processor and a user,
wherein the nonvolatile memory apparatus comprises:
a memory cell array;
a WD/SA configured to program data into the memory cell array or read data provided from the memory cell array; and
an I/O controller configured to receive the read data provided from the memory cell array from the WD/SA, decide a coding mode based on comparison data obtained by comparing write data with the read data, encode the write data according to the coding mode, and provide the encoded data to the WD/SA.

15. The data processing system according to claim 14, further comprising a communication module controlled by the processor.

16. An operating method of a nonvolatile memory apparatus, comprising the steps of:
reading data from a memory cell array in which program is to be performed according to a write command;
deciding a coding mode based on comparison data obtained by comparing write data and the read data from the memory cell array;
is encoding the write data according to the coding mode; and
programming the encoded data into a memory cell.

17. The operating method according to claim 16, wherein the step of deciding the coding mode comprises the step of deciding comparison data occupying the largest portion of the comparison data as a coding mode.

18. The operating method according to claim 16, wherein the step of generating the comparison data comprises step of generating inverted bit information between the write data and the read data from the memory cell array.

19. The operating method according to claim 16, wherein the step of programming the encoded data comprises a step of prohibit a program operation of a memory cell, in which the corresponding write data is to be programmed, when the comparison data is identical to the coding mode.

20. The operating method according to claim 16, wherein the step of programming the encoded data comprises a step of add a tail mode as the coding mode into the encoded data and programming the encoded data.

21. The operating method according to claim 16, further is comprising the steps of:
reading data from a memory cell in which a read operation is to be performed, as a read command is inputted from the host; and
decoding the data read from the memory cell according to the coding mode.
